(19) United States
(12) Patent Application Publication
(10) Pub. No.: US 2025/0212326 A1
(43) Pub. Date: Jun. 26, 2025

(54) PRINTED CIRCUIT BOARD

(71) Applicant: SAMSUNG ELECTRO-MECHANICS CO., LTD., Suwon-si (KR)

(72) Inventors: Sang Jong LEE, Suwon-si (KR); Hee Soo YOON, Suwon-si (KR); Min Cheol PARK, Suwon-si (KR); Jung Ho SHIM, Suwon-si (KR); Hyun Sang KWAK, Suwon-si (KR)

(73) Assignee: SAMSUNG ELECTRO-MECHANICS CO., LTD., Suwon-si (KR)

(21) Appl. No.: 18/956,455

(22) Filed: Nov. 22, 2024

(30) Foreign Application Priority Data
Dec. 20, 2023 (KR) 10-2023-0187033

(51) Int. Cl. H05K 1/05; H05K 1/11

(52) U.S. Cl. CPC H05K 1/053; H05K 1/115; H05K 2201/08

(57) ABSTRACT

A printed circuit board includes a magnetic structure including a magnetic layer having a through-hole, an insulating film disposed on a wall surface of the through-hole, the insulating film including an inorganic insulating material, and a conductor layer disposed on the insulating film, the conductor layer filling at least a portion of the through-hole, the conductor layer including a metal, an insulating layer covering at least a portion of the magnetic structure, a wiring layer disposed on or in the insulating layer, and a via layer disposed in the insulating layer, the via layer including a first connection via connecting the conductor layer to the wiring layer.

### CROSS-REFERENCE TO RELATED APPLICATION(S)

This application claims benefit of priority to Korean Patent Application No. 10-2023-0187033 filed on Dec. 20, 2023 in the Korean Intellectual Property Office, the disclosure of which is incorporated herein by reference in its entirety.

### TECHNICAL FIELD

The present disclosure relates to a printed circuit board.

Recently, in order to slim down semiconductor chips and increase power efficiency thereof, it has been required to embed various passive devices such as capacitors and inductors in a package substrate. As compared to a chip component, according to the related art, an inductor has been required to have improved inductance by changing a material and a structure thereof.

### SUMMARY

An aspect of the present disclosure provides a printed circuit board for improving capacitance and inductance of an inductor.

Another aspect of the present disclosure provides a printed circuit board that is further slimmed down and has a higher degree of integration.

According to an aspect of the present disclosure, a through-hole may be formed in a magnetic layer, and may then be filled with an insulating film and a conductor layer to form a magnetic structure, and the magnetic structure may be embedded in a substrate to directly form a magnetic composite inductor (MCI).

For example, a printed circuit board according to an aspect of the present disclosure may include a magnetic structure including a magnetic layer having a through-hole, an insulating film disposed on a wall surface of the through-hole, the insulating film including an inorganic insulating material, and a conductor layer disposed on the insulating film, the conductor layer filling at least a portion of the through-hole, the conductor layer including a metal, an insulating layer covering at least a portion of the magnetic structure, a wiring layer disposed on or in the insulating layer, and a via layer disposed in the insulating layer, the via layer including a connection via connecting the conductor layer to the wiring layer.

For example, a printed circuit board according to another aspect of the present disclosure may include a magnetic structure including a magnetic layer having a through-hole, an insulating film disposed on a wall surface of the through-hole, and a conductor layer disposed on the insulating film, the conductor layer filling at least a portion of the through-hole, an insulating layer covering at least a portion of the magnetic structure, a wiring layer disposed on or in the insulating layer, and a via layer disposed in the insulating layer, the via layer including a connection via connecting the conductor layer to the wiring layer. A first surface of the magnetic layer, a first surface of the insulating film, and a first surface of the conductor layer may be substantially coplanar with each other. A second surface of the magnetic layer, a second surface of the insulating film, and a second surface of the conductor layer may be substantially coplanar with each other.

According to example embodiments of the present disclosure, a printed circuit board may improve capacitance and inductance of an inductor.

In addition, the printed circuit board may be further slimmed down, and may have a higher degree of integration.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram of an example of an electronic device system;

FIG. 2 is a schematic perspective view of an example of an electronic device;

FIG. 3 is a schematic cross-sectional view of an example of a printed circuit board;

FIGS. 4A to 4I are schematic cross-sectional views of an example of manufacturing a magnetic structure of the printed circuit board in FIG. 3;

FIG. 5 is a schematic cross-sectional view of another example of a printed circuit board;

FIGS. 6A to 6J are schematic cross-sectional views of an example of manufacturing a magnetic structure of the printed circuit board in FIG. 5;

FIG. 7 is a schematic cross-sectional view of another example of a printed circuit board;

FIGS. 8A to 8K are schematic cross-sectional views of an example of manufacturing a magnetic structure of the printed circuit board in FIG. 7; and

FIGS. 9A to 9F are schematic plan views of various examples of a coil applicable to the printed circuit boards in FIGS. 3, 5, and 7.

### DETAILED DESCRIPTION

Hereinafter, example embodiments of the present disclosure are described with reference to the accompanying drawings. The shapes and sizes of components in the drawings may be exaggerated or reduced for clearer description.

### Electronic Device

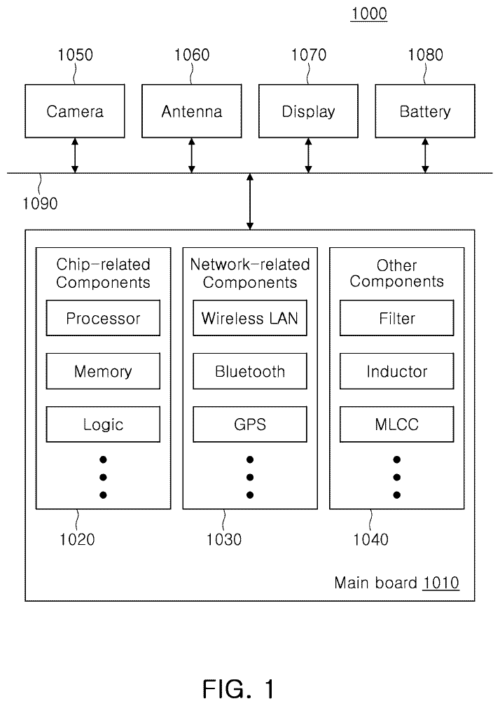

FIG. 1 is a schematic block diagram of an example of an electronic device system.

Referring to the drawing, an electronic device 1000 may accommodate a mainboard 1010. The mainboard 1010 may include chip-related components 1020, network-related components 1030, and other components 1040, physically or electrically connected thereto. Such components may be connected to other components to be described below to form various signal lines 1090.

The chip-related components 1020 may include a memory chip such as a volatile memory (for example, a dynamic random access memory (DRAM)), a non-volatile memory (for example, a read only memory (ROM)), or a flash memory, an application processor chip such as a central processor (for example, a central processing unit (CPU)), a graphics processor (for example, a graphics processing unit (GPU)), a digital signal processor, a cryptographic processor, a microprocessor, or a microcontroller, and a logic chip such as an analog-to-digital converter or an application-specific integrated circuit (ASIC). However, the chip-related components 1020 are not limited thereto, and may include other types of chip-related components. In addition, the chip-related components 1020 may be combined with each other. The chip-related components 1020 may be in the form of a package including the above-described chip or electronic component.

The network-related components 1030 may include protocols such as wireless fidelity (Wi-Fi) (Institute of Electrical And Electronics Engineers (IEEE) 802.11 family or the like), worldwide interoperability for microwave access (WiMAX) (IEEE 802.16 family or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the above-described protocols. However, the network-related components 1030 are not limited thereto, and may also include a variety of other wireless or wired standards or protocols. In addition, the network-related components 1030 may be combined with each other, together with the chip-related components 1020 described above.

The other components 1040 may include a high-frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, the other components 1040 are not limited thereto, and may also include passive components used for various other purposes, or the like. In addition, the other components 1040 may be combined with each other, together with the chip-related components 1020 or the network-related components 1030 described above.

Depending on a type of the electronic device 1000, the electronic device 1000 may include other components that may be or may not be physically or electrically connected to the mainboard 1010. The other components may include, for example, a camera module 1050, an antenna module 1060, a display 1070, a battery 1080, and the like. However, the other components are limited thereto, and may be an audio codec, a video codec, a power amplifier, a compass, an accelerometer, a gyroscope, a speaker, a mass storage unit (for example, a hard disk drive), a compact disk (CD), a digital versatile disk (DVD), or the like. In addition, the other components may also include other components used for various purposes depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device to process data.

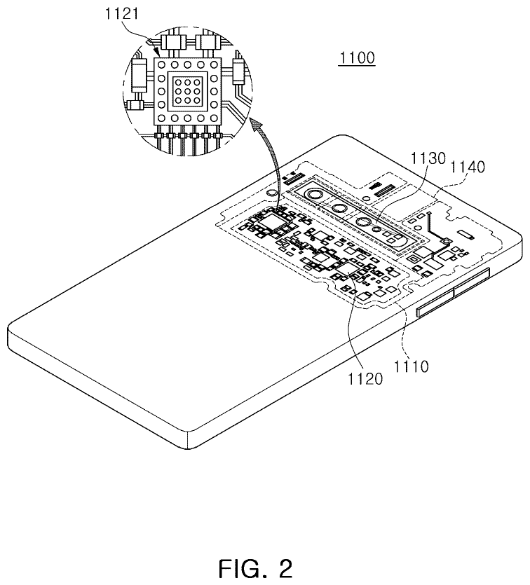

FIG. 2 is a schematic perspective view of an example of an electronic device.

Referring to the drawing, an electronic device may be, for example, a smartphone 1100. The motherboard 1110 may be accommodated in the smartphone 1100, and various electronic components 1120 may be physically and/or electrically connected to the motherboard 1110. In addition, other electronic components that may be or may not be physically and/or electrically connected to the motherboard 1110 may be accommodated therein, such as a camera module 1130 and/or a speaker 1140. A portion of the electronic components 1120 may be the chip-related components described above, for example, a component package 1121, but the present disclosure is not limited thereto. The component package 1121 may be in the form of a printed circuit board on which electronic components including active components and/or passive components are surface-mounted. The electronic device is not necessarily limited to the smartphone 1100, and may be other electronic devices, as described above.

### Printed Circuit Board

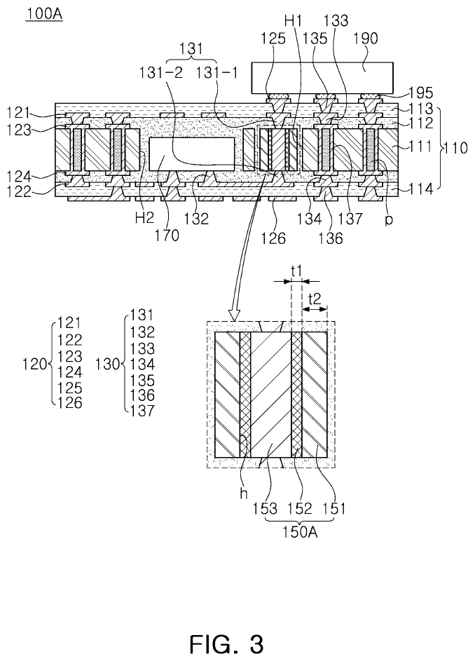

FIG. 3 is a schematic cross-sectional view of an example of a printed circuit board.

Referring to the drawing, a printed circuit board 100A according to an example may include a magnetic structure 150A including a magnetic layer 151 having a through-hole h, an insulating film 152 disposed on a wall surface of the through-hole h, and a conductor layer 153 disposed on the insulating film 152, the conductor layer 153 filling at least a portion of the through-hole h, an insulating layer 110 covering at least a portion of the magnetic structure 150A, a wiring layer 120 disposed on or in the insulating layer 110, and a via layer 130 disposed in the insulating layer 110. The printed circuit board 100A may further include a first electronic component 170 buried in the insulating layer 110, and a second electronic component 190 mounted on the insulating layer 110, as necessary.

The insulating film 152 may include an inorganic insulating material. For example, the insulating film 152 may include an inorganic oxide film. For example, the inorganic insulating material, included in the insulating film 152, may include at least one of Al₂O₃, TiO₂, ZnO, ZnO₂, ZrO₂, SnO, SnO₂, HfO₂, and SiO₂, but the present disclosure is not limited thereto. The insulating film 152 may be formed using a deposition process using the inorganic insulating material described above, and thus may be formed to have a small thickness. Accordingly, the magnetic layer 151 may be formed to be sufficiently thick. For example, in cross-section, in a direction, perpendicular to the wall surface of the through-hole h, a width t1 of the insulating film 152 between the wall surface of the through-hole h and a side surface of the conductor layer 153 may be less than a width t2 of the magnetic layer 151 between the wall surface of the through-hole h and an external side surface of the magnetic layer 151. For example, in cross-section, in a direction, perpendicular to the wall surface of the through-hole h, the width t1 of the insulating film 152 between the wall surface of the through-hole h and the side surface of the conductor layer 153 may be 2 μm or less, for example, about 1 μm to 2 μm. Accordingly, an inductor, such as a magnetic composite inductor (MCI), formed using magnetic structure 150 in the printed circuit board 100A, may have increased capacitance, and may also have increased inductance.

An upper surface and a lower surface of the magnetic structure 150 may be substantially flat. For example, as in a process to be described below, a planarization process, such as polishing or the like, may be performed. Accordingly, the upper surface of the magnetic layer 151, an upper surface of the insulating film 152, and an upper surface of the conductor layer 153 may be substantially coplanar with each other. In addition, the lower surface of the magnetic layer 151, a lower surface of the insulating film 152, and a lower surface of the conductor layer 153 may be substantially coplanar with each other. Accordingly, the insulating layer 110 covering the same may also have more excellent flatness. Accordingly, the wiring layer 120 and the via layer 130 may be more easily formed.

A plurality of magnetic structures 150 may be provided. The plurality of magnetic structures 150 may be disposed to be spaced apart from each other. The conductor layers 153 of the plurality of magnetic structures 150 may be connected to each other through the wiring layer 120 and the via layer 130 to form one or more coils.

Alternatively, the magnetic layer 151 of the magnetic structure 150 may have a plurality of through-holes h, and an insulating film 152 and a conductor layer 153 may be formed in each of the plurality of through-holes h. The conductor layers 153 of the plurality of through-holes h may be connected to each other through the wiring layer 120 and the via layer 130 to form one or more coils. Alternatively, both the conductor layer 153 of the magnetic structure 150 and the conductor layer 153 of the through-hole H may be combined with each other to form one or more coils. For example, at least one of the plurality of magnetic structures 150 may have a plurality of through-holes h, and an insulating film 152 and a conductor layer 153 may be formed in each of the plurality of through-holes h, and the conductor layer 153 of each of the plurality of magnetic structures 150 and/or the conductor layer 153 of each of the plurality of through-holes h may be connected to each other through the wiring layer 120 and the via layer 130 to form one or more coils. Accordingly, an MCI may be formed in the printed circuit board 100A. Accordingly, the printed circuit board 100A may be further slimmed down, and may have a higher degree of integration. For example, a mounting area on the printed circuit board 100A may be increased, and a current path between an electronic component and an inductor may be minimized.

The via layer 130 may include a first connection via 131 connecting the conductor layer 153 of the magnetic structure 150 to the wiring layer 120. For example, the via layer 130 may include a first-first connection via 131-1 passing through a portion of an upper side of the insulating layer 110, the first-first connection via 131-1 directly connected to an upper surface of the conductor layer 153, and a first-second connection via 131-2 passing through a portion of a lower side of the insulating layer 110, the first-second connection via 131-2 directly connected to a lower surface of the conductor layer 153, and the first connection via 131 may include first-first and first-second connection vias 131-1 and 131-2. As described, in the printed circuit board 100A according to an example, the conductor layer 153 of the magnetic structure 150 may be directly connected to the first connection via 131 of the via layer 130. Accordingly, a process of manufacturing the printed circuit board 100A may be further simplified, and the printed circuit board 100A may be further slimmed down, and may have a higher degree of integration.

The first electronic component 170 may be disposed in the insulating layer 110, and may include at least one of a voltage regulator and a power management integrated circuit, but the present disclosure is not limited thereto. The first electronic component 170 may be connected to at least a portion of the conductor layer 153 of the magnetic structure 150 through the wiring layer 120 and the via layer 130. In addition, the second electronic component 170 may be disposed on the insulating layer 110, and may include at least one of a memory chip, an application processor chip, and a logic chip, but the present disclosure is not limited thereto. The second electronic component 190 may also be connected to at least another portion of the conductor layer 153 of the magnetic structure 150 through the wiring layer 120 and the via layer 130. As described, the first and second electronic components 170 and 190 may be disposed on the inside and the outside of the printed circuit board 100A to be connected to the conductor layer 153 of the magnetic structure 150, such that the printed circuit board 100A may be further slimmed down, and may have a higher degree of integration. For example, a mounting area on the printed circuit board 100A may be further increased, and a current path between the first and second electronic components 170 and 190 and the MCI may be minimized.

Hereinafter, components of the printed circuit board 100A according to an example will be described in more detail with reference to the drawings.

The insulating layer 110 may include first to fourth insulating layers 111, 112, 113, and 114. The first insulating layer 111 may have a first through portion H1 in which at least a portion of the magnetic structure 150 is disposed, and a second through portion H2 in which at least a portion of the first electronic component 170 is disposed. The first insulating layer 111 may be a core layer. The second insulating layer 112 may cover at least a portion of each of the first insulating layer 111, the magnetic structure 150, and the first electronic component 170, and may fill at least a portion of each of the first and second through portions H1 and H2. The third insulating layer 113 may be disposed on an upper surface of the second insulating layer 112. The fourth insulating layer 114 may be disposed on a lower surface of the second insulating layer 112. The second to fourth insulating layers 112, 113, and 114 may be build-up layers. A build-up layer may be further formed on each of the third and fourth insulating layers 113 and 114. The first and second through portions H1 and H2 may respectively pass through a space between an upper surface and a lower surface of the first insulating layer 111, but may pass through only a portion of the first insulating layer 111 from the upper surface. For example, the first and second through portions H1 and H2 may be a through-cavity and/or a blind cavity.

The first to fourth insulating layers 111, 112, 113, and 114 may include an inorganic insulating material and/or an organic insulating material. As a non-limited example, the first to fourth insulating layers 111, 112, 113, and 114 may all include an organic insulating material. Alternatively, the first insulating layer 111 may include an inorganic insulating material, and the second to fourth insulating layers 112, 113, and 114 may include an organic insulating material. However, the present disclosure is not limited thereto. The organic insulating material may include a thermosetting resin such as an epoxy resin, a thermoplastic resin such as polyimide, or an inorganic filler, an organic filler, and/or a glass fiber (glass cloth and/or glass fabric), together with the resin. For example, the organic insulating material may be a copper clad laminate (CCL), a prepreg (PPG), an Ajinomoto build-up film (ABF), a photoimageable dielectric (PID) or the like, but the present disclosure is not limited thereto. The inorganic insulating material may include a glass substrate, a silicon substrate, and/or a ceramic substrate. For example, the glass substrate may include glass. Glass may include, for example, pure silicon dioxide (about 100% SiO₂), soda lime glass, borosilicate glass, alumino-silicate glass, or the like. However, the present disclosure is not limited thereto, and an alternative glass material, such as fluorine glass, phosphate glass, chalcogen glass, or the like, may also be used as a material of a glass layer. In addition, other additives may be further included to form glass having specific physical properties. The above-described additives may magnesium, calcium, manganese, aluminum, lead, boron, iron, chromium, potassium, sulfur, and antimony, as well as calcium carbonate (for example, lime) and sodium carbonate (for example, soda), and a carbonate and/or an oxide of the above-described elements and other elements. Glass may be distinguished from a glass fiber (glass cloth and/or glass fabric) included in the organic insulating material. In addition, the silicon substrate may include silicon (Si), and may include an oxide layer formed on silicon (Si), as necessary. In addition, the silicon substrate may include a nitride layer formed on the oxide layer. The oxide layer may include a silicon oxide film, and the nitride layer may include a silicon nitride film, but the present disclosure is not limited thereto. In addition, the ceramic substrate may include ceramic, and ceramic may include, for example, alumina (Al₂O₃), aluminum nitride (AlN), silicon carbide (SiC), silicon nitride (Si₃N₄), or the like, but the present disclosure is not limited thereto.

The wiring layer 120 may include a first wiring layer 121 disposed on an upper surface of the second insulating layer 112, a second wiring layer 122 disposed on a lower surface of the second insulating layer 112, a third wiring layer 123 disposed on an upper surface of the first insulating layer 111, the third wiring layer 123 at least partially buried in the second insulating layer 112, a fourth wiring layer 124 disposed on a lower surface of the first insulating layer 111, the fourth wiring layer 124 at least partially buried in the second insulating layer 112, a fifth wiring layer 125 disposed on an upper surface of the third insulating layer 113, and a sixth wiring layer 126 disposed on a lower surface of the fourth insulating layer 114. When the insulating layer 110 further includes a build-up layer, the wiring layer 120 may further include a build-up wiring layer. The first to sixth wiring layers 121, 122, 123, 124, 125, and 126 may respectively include a metal. The metal may include copper (Cu), aluminum (Al), silver (Ag), tin (Sn), gold (Au), nickel (Ni), lead (Pb), titanium (Ti), and/or alloys thereof. The metal may preferably include copper (Cu), but the present disclosure is not limited thereto. The first to sixth wiring layers 121, 122, 123, 124, 125, and 126 may perform various functions according to a design thereof. For example, a signal pattern, a power pattern, a ground pattern, and the like may be included. The patterns may respectively have various forms such as a line, a plane, a pad, and the like. The first to sixth wiring layers 121, 122, 123, 124, 125, and 126 may respectively include a seed layer and a plating layer formed on the seed layer. The seed layer may be an electroless plating layer (or chemical copper) and/or a sputtering layer, and the plating layer may be an electrolytic plating layer (or electrolytic copper), but the present disclosure is not limited thereto.

The via layer 130 may include a first-first connection via 131-1 passing through a portion of an upper side of the second insulating layer 112, the first-first connection via 131-1 connecting an upper surface of the conductor layer 153 to at least a portion of the first wiring layer 121, a first-second connection via 131-2 passing through a portion of a lower side of the second insulating layer 112, the first-second connection via 131-2 connecting a lower surface of the conductor layer 153 to at least a portion of the second wiring layer 122, a second connection via 132 passing through another portion of the lower side of the second insulating layer 112, the second connection via 132 connecting the first electronic component 170 to at least another portion of the second wiring layer 122, a third connection via 133 passing through another portion of the upper side of the second insulating layer 112, the third connection via 133 connecting at least a portion of the first wiring layer 121 and at least a portion of the third wiring layer 123 to each other, a fourth connection via 134 passing through another portion of the lower side of the second insulating layer 112, the fourth connection via 134 connecting at least a portion of the second wiring layer 122 and at least a portion of the fourth wiring layer 124 to each other, a fifth connection via 135 passing through the third insulating layer 113, the fifth connection via 135 connecting at least a portion of the first wiring layer 121 and at least a portion of the fifth wiring layer 125 to each other, a sixth connection via 136 passing through the fourth insulating layer 114, the sixth connection via 136 connecting at least a portion of the second wiring layer 122 and at least a portion of the sixth wiring layers 126 to each other, and a through via passing through first insulating layer 111, the through via connecting at least a portion of the third wiring layer 123 and at least a portion of the fourth wiring layer 124 to each other. The first connection via 131 may include first-first and first-second connection vias 131-1 and 131-2. When the insulating layer 110 further includes a build-up insulating layer, the via layer 130 may further include a build-up via layer.

The first to sixth connection vias 131, 132, 133, 134, 135, and 136 and the through via 137 may respectively include a metal. The metal may include copper (Cu), aluminum (Al), silver (Ag), tin (Sn), gold (Au), nickel (Ni), lead (Pb), titanium (Ti), and/or alloys thereof. The metal may preferably include copper (Cu), but the present disclosure is not limited thereto. The first to sixth connection vias 131, 132, 133, 134, 135, and 136 and the through via 137 may respectively include a filled via, filling a via hole or a through-hole, but may also include a conformal via disposed along a wall surface of the via hole or the through-hole. The first to sixth connection vias 131, 132, 133, 134, 135, and 136 and the through via 137 may respectively perform various functions according to a design thereof. For example, a ground via, a power via, a signal via, or the like may be included. The first to sixth connection vias 131, 132, 133, 134, 135, and 136 and the through via 137 may respectively include an electroless plating layer (or chemical copper) and an electrolytic plating layer (or electrolytic copper). A sputtering layer may be included instead of the electroless plating layer (or chemical copper), or both may be included. The first to sixth connection vias 131, 132, 133, 134, 135, and 136 may respectively have a tapered shape in cross-section. The through via 137 may have a pillar shape in cross-section. A filler p may be disposed in the through via 137, and the filler p may include an insulating material or a conductive material.

The magnetic structure 150 may include a magnetic layer 151 having a through-hole h, an insulating film 152 disposed on a wall surface of the through-hole h, and a conductor layer 153 disposed on the insulating film 152 to fill at least a portion of the through-hole h. A plurality of magnetic structures 150 may be provided, and the plurality of magnetic structures 150 may be disposed to be spaced apart from each other. The conductor layers 153 of the plurality of magnetic structures 150 may be connected to each other through the wiring layer 120 and the via layer 130 to form one or more coils. Alternatively, the magnetic layer 151 of the magnetic structure 150 may have a plurality of through-holes h, and an insulating film 152 and a conductor layer 153 may be formed in each of the plurality of through-holes h. The conductor layers 153 of the plurality of through-holes h may be connected to each other through the wiring layer 120 and the via layer 130 to form one or more coils. Alternatively, both the conductor layer 153 of the magnetic structure 150 and the conductor layer 153 of the through-hole h may be combined with each other to form one or more coils. For example, at least one of the plurality of magnetic structures 150 may have a plurality of through-holes h, and an insulating film 152 and a conductor layer 153 may be formed in each of the plurality of through-holes h, and the conductor layer 153 of each of the plurality of magnetic structures 150 and/or the conductor layer 153 of each of the plurality of through-holes h may be connected to each other through the wiring layer 120 and the via layer 130 to form one or more coils. Accordingly, an MCI may be formed in the printed circuit board 100A.

The magnetic layer 151 may include a magnetic material. The magnetic material may include, for example, a ferrite-based material, a permalloy-based material, or the like. For example, the magnetic material may include Ni-based ferrite, Ni—Zn-based ferrite, Ni—Zn—Cu-based ferrite, Fe—Si—Al (Sendust), Ni—Mo—Fe (a molypermalloy powder (MPP) core), Ni—Fe (a high flux core), or the like, but the present disclosure is not limited thereto, and the magnetic material may include other known ferrite-based materials, permalloy-based materials, or the like. In addition, various types of magnetic materials including other magnetic powders and/or magnetic particles may be used. The magnetic layer 151 may be cured in the form of a magnetic film or a magnetic sheet, and may be disposed in a first through portion H1. Accordingly, the magnetic layer 151 may be disposed to be spaced apart from the first insulating layer 111.

The insulating film 152 may include an insulating material, for example, an inorganic insulating material. For example, the insulating film 152 may include an inorganic oxide film. For example, the inorganic insulating material, included in the insulating film 152, may include at least one of Al₂O₃, TiO₂, ZnO, ZnO₂, ZrO₂, SnO, SnO₂, HfO₂, and SiO₂, but the present disclosure is not limited thereto. The insulating film 152 may be formed using a deposition process using an inorganic insulating material to have a small thickness. For example, in cross-section, in a direction, perpendicular to a wall surface of the through-hole h, a width t1 of the insulating film 152 between the wall surface of the through-hole h and a side surface of the conductor layer 153 may be less than a width t2 of the magnetic layer 151 between the wall surface of the through-hole h and an external side surface of the magnetic layer 151. For example, in cross-section, in a direction, perpendicular to the wall surface of the through-hole h, the width t1 of the insulating film 152 between the wall surface of the through-hole h and the side surface of the conductor layer 153 may be 2 μm or less, for example, about 1 μm to about 2 μm.

The conductor layer 153 may include a conductive material, such as a metal. For example, the conductor layer 153 may include a metal pillar. The metal pillar may be, for example, a cylinder, an elliptical pillar, a rectangular pillar, or the like, but the present disclosure is not limited thereto. For example, the metal, included in the conductor layer 153, may include copper (Cu), aluminum (Al), silver (Ag), tin (Sn), gold (Au), nickel (Ni), lead (Pb), titanium (Ti), and/or alloys thereof. The metal may preferably include copper (Cu), but the present disclosure is not limited thereto. The conductor layer 153 may include a seed layer and a plating layer formed on the seed layer. The seed layer may be an electroless plating layer (or chemical copper) and/or a sputtering layer, and the plating layer may be an electrolytic plating layer (or electrolytic copper), but the present disclosure is not limited thereto. The seed layer may be disposed on a lower surface and a side surface of the plating layer using a planarization process, such as polishing, to be described below, but may not be disposed on an upper surface of the plating layer, and an upper surface of the seed layer and the upper surface of the plating layer may be substantially coplanar with each other. For example, the seed layer may be disposed to have a predetermined small thickness to entirely surround the lower and side surfaces excluding the upper surface of the plating layer, and the plating layer may fill a space formed by the seed layer. However, the present disclosure is not limited thereto, and the seed layer, covering the lower surface of the plating layer, may also be removed using a polishing process. In this case, the seed layer may be disposed only on the side surface of the plating layer, and the seed layer and the plating layer may have upper and lower surfaces substantially coplanar with each other. For example, the seed layer may be disposed to have a predetermined small thickness to entirely surround the side surface of the plating layer.

The first electronic component 170 may include at least one of a voltage regulator and a power management integrated circuit. A plurality of first electronic components 170 may be provided. In this case, the plurality of first electronic components 170 may be disposed in the second through portion H2, or may be respectively disposed in a plurality of second through portions H2. The first electronic component 170 may further include integrated passive devices (IPD), as necessary. The IPD may be an integrated passive component (IPC) or an embedded passive component (EPC) in other terms.

The second electronic component 190 may include a semiconductor chip. The semiconductor chip may be an integrated circuit (IC) die in which hundreds to millions of devices are integrated in a single chip. The integrated circuit die may be formed based on an active wafer. In this case, silicon (Si), germanium (Ge), gallium arsenide (GaAs), or the like may be used as a base material of each body. Various circuits may be formed in the body. A connection pad may be formed on a front surface of the body, and the connection pad may include a conductive material such as aluminum (Al), copper (Cu), or the like. The semiconductor chip may include a memory chip such as a volatile memory (for example, DRAM), a non-volatile memory (for example, ROM), or a flash memory, an application processor chip such as a central processing unit (for example, a CPU), a graphic processing unit (for example, a GPU), a digital signal processor, a cryptographic processor, a microprocessor, or a microcontroller, and a logic chip such as an analog-to-digital converter or an application-specific IC (ASIC), but the present disclosure is not limited thereto. The second electronic component 190 may be connected to the fifth wiring layer 125 through an electrical connection metal 195. The electrical connection metal 195 may include a low melting point metal such as tin (Sn), for example, solder, but the present disclosure is not limited thereto.

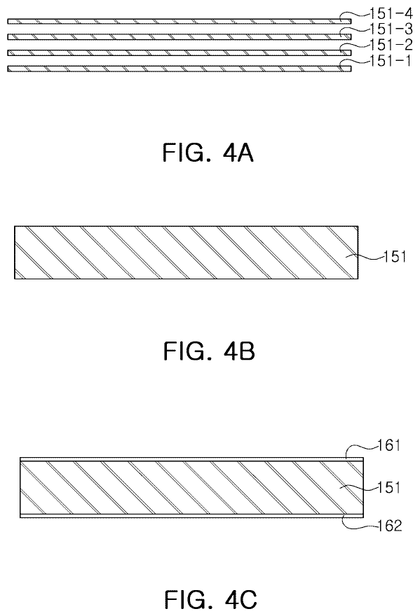

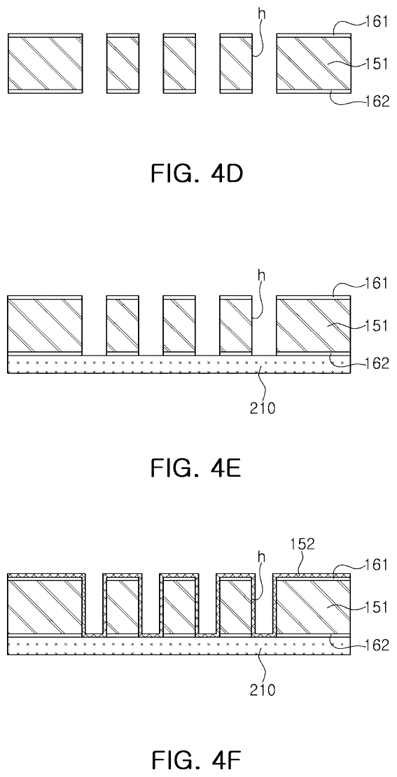

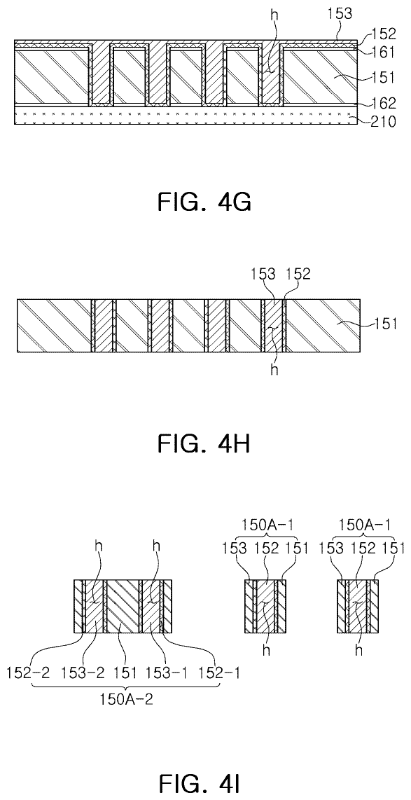

FIGS. 4A to 4I are schematic cross-sectional views of an example of manufacturing a magnetic structure of the printed circuit board in FIG. 3.

Referring to FIG. 4A, a plurality of magnetic film 151-1, 151-2, 151-3, and 151-4 may be prepared. The plurality of magnetic film 151-1, 151-2, 151-3, and 151-4 may include substantially the same material, for example, the magnetic material described above.

Referring to FIG. 4B, the plurality of magnetic film 151-1, 151-2, 151-3, and 151-4 may be stacked, compressed, and then sintered. As a result, a magnetic layer 151 may be formed.

Referring to FIG. 4C, first and second cover layers 161 and 162 may respectively be attached to upper and lower surfaces of the magnetic layer 151, as necessary. The first and second cover layers 161 and 162 may include an insulating material, and a material thereof is not particularly limited.

Referring to FIG. 4D, a plurality of through-holes h may be formed in the magnetic layer 151. The plurality of through-holes h may be formed using a CNC drill or the like. The plurality of through-holes h may also pass through the first and second cover layers 161 and 162.

Referring to FIG. 4E, a carrier film 210 may be attached to a lower side of the magnetic layer 151. For example, the carrier film 210 may be attached to a lower surface of the second cover layer 162. A material of the carrier film 210 may not be particularly limited.

Referring to FIG. 4F, an insulating film 152 may be formed on the magnetic layer 151. For example, the thin insulating film 152 may be formed using a deposition process such as a chemical vapor deposition (CVD) or an atomic layer deposition (ALD). The insulating film 152 may cover an upper surface of the first cover layer 161, a wall surface of each of the plurality of through-holes h, and an exposed upper surface of the carrier film 210.

Referring to FIG. 4G, a conductor layer 153 may be formed on the insulating film 152. The conductor layer 153 may fill a remaining space of each of the plurality of through-holes h. The conductor layer 153 may be formed using a plating process. For example, the conductor layer 153 may be formed using electroless plating, electrolytic plating, or the like.

Referring to FIG. 4H, the carrier film 210 may be removed to planarize upper and lower surfaces of the magnetic layer 151. During such a process, the first and second cover layers 161 and 162 disposed on the upper and lower surfaces of the magnetic layer 151, the insulating film 152, and the conductor layer 153 may be removed. An upper side and/or a lower side of the magnetic layer 151 may be partially removed, as necessary, and at least a portion of each of the insulating film 152 and the conductor layer 153 may be further removed. Accordingly, flat upper and lower surfaces may be provided. As the planarization process, for example, a polishing process, such as chemical mechanical polishing (CMP), may be used.

Referring to FIG. 4I, a cutting process may be performed. A plurality of magnetic structures 150A-1 and 150A-2 may be formed using the cutting process. At least one magnetic structure 150A-2, among the plurality of magnetic structures 150A-1 and 150A-2, may have a plurality of through-holes h, and insulating films 152-1 and 152-2 and conduction layers 153-1 and 153-2 may be respectively disposed in the plurality of through-holes h.

The plurality of magnetic structures 150A-1 and 150A-2, applicable to the printed circuit board 100A according to an example, may be formed using a series of processes. Other contents may be substantially the same as those described in connection with the printed circuit board 100A according to an example, and thus repeated descriptions will be omitted.

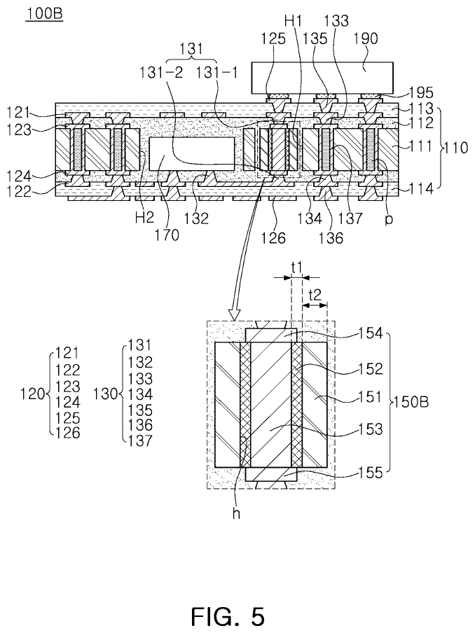

FIG. 5 is a schematic cross-sectional view of another example of a printed circuit board.

Referring to the drawing, as compared to the printed circuit board 100A according to an example, in a printed circuit board 100B according to another example, a magnetic structure 150B may further include a first pad 154 disposed on an upper surface of a conductor layer 153 and an upper surface of an insulating film 152, the first pad 154 connected to the upper surface of the conductor layer 153, and a second pad 155 disposed on a lower surface of the conductor layer 153 and a lower surface of the insulating film 152, the second pad 155 connected to the lower surface of the conductor layer 153. In this case, first-first and first-second connection vias 131-1 and 131-2 may be respectively connected to the first and second pads 154 and 155. Accordingly, the first and second pads 154 and 155 may be easily connected to the first-first and first-second connection vias 131-1 and 131-2, thereby obtaining more excellent reliability.

The first and second pads 154 and 155 may respectively include a metal. For example, the metal, included in each of the first and second pads 154 and 155, may include copper (Cu), aluminum (Al), silver (Ag), tin (Sn), gold (Au), nickel (Ni), lead (Pb), titanium (Ti), and/or alloys thereof. The metal may preferably include copper (Cu), but the present disclosure is not limited thereto. The first and second pads 154 and 155 may respectively include a seed layer and a plating layer formed on the seed layer. The seed layer may be an electroless plating layer (or chemical copper) and/or a sputtering layer, and the plating layer may be an electrolytic plating layer (or electrolytic copper), but the present disclosure is not limited thereto. The seed layers of the first and second pads 154 and 155 may have a relatively small thickness to respectively cover upper and lower surfaces of the conductor layer 153 and the insulating film 152, and the plating layers of the first and second pads 154 and 155 may have a relatively large thickness to respectively cover upper and lower surfaces of the seed layers of the first and second pads 154 and 155. Other contents may be substantially the same as those described in connection with the printed circuit board 100A according to an example, and thus repeated descriptions will be omitted.

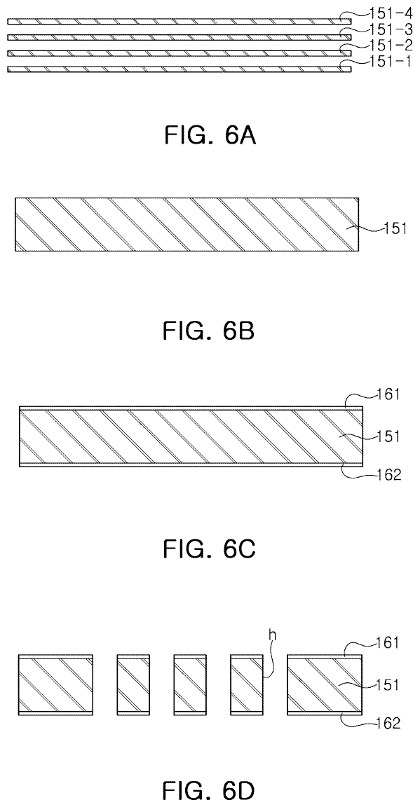

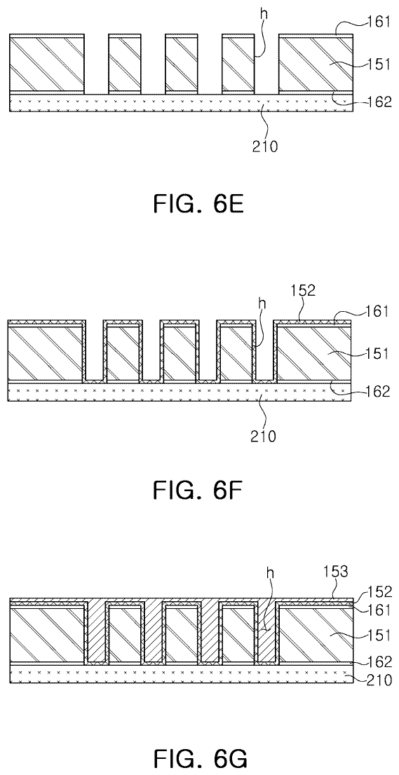

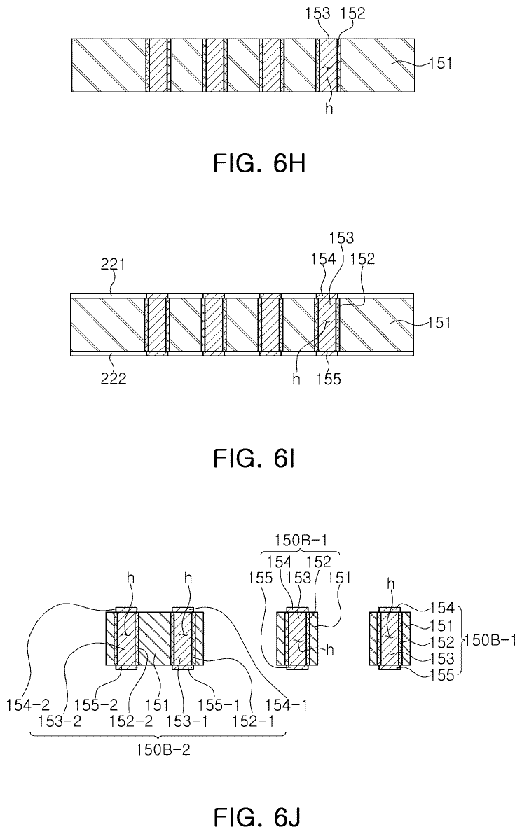

FIGS. 6A to 6J are schematic cross-sectional views of an example of manufacturing a magnetic structure of the printed circuit board in FIG. 5.

Referring to FIGS. 6A to 6H, a process, substantially the same as that described with reference to FIGS. 4A to 4H, may be performed.

Referring to FIG. 6I, first and second resist layers 221 and 222, respectively having an opening pattern, may be formed on upper and lower surfaces of the magnetic layer 151, respectively, and the opening patterns may be filled with plating to form first and second pads 154 and 155. The first and second resist layers 221 and 222 may be formed by coating and curing solder resist or laminating a solder resist film. The first and second resist layers 221 and 222 may remain around the first and second pads 154 and 155, as necessary, even after a cutting process to be described below.

Referring to FIG. 6J, a cutting process may be performed. A plurality of magnetic structures 150B-1 and 150B-2 may be formed using the cutting process. At least one magnetic structure 150B-2, among the plurality of magnetic structures 150B-1 and 150B-2, may have a plurality of through-holes h, insulating films 152-1 and 152-2 and conduction layers 153-1 and 153-2 may be respectively disposed in the plurality of through-holes h, and first pads 154-1 and 154-2 and the second pads 155-1 and 155-2 may be respectively disposed on upper sides and lower sides of the plurality of through-holes h.

The plurality of magnetic structures 150B-1 and 150B-2, applicable to the printed circuit board 100B according to another example, may be formed using a series of processes. Other contents may be substantially the same as those described in connection with the printed circuit board 100A according to an example and the printed circuit board 100B according to another example, and thus repeated descriptions will be omitted.

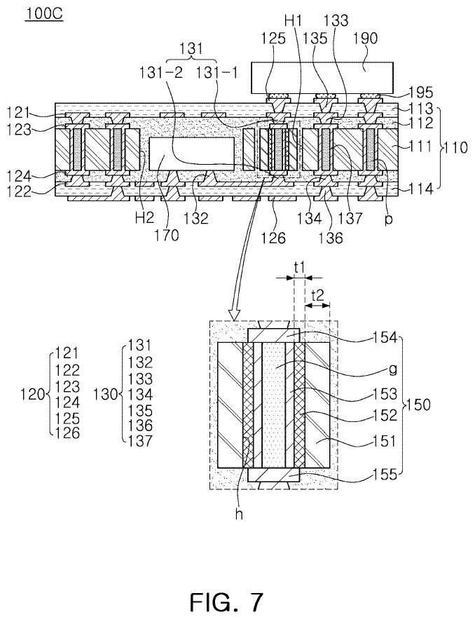

FIG. 7 is a schematic cross-sectional view of another example of a printed circuit board.

Referring to the drawing, as compared to the printed circuit board 100B according to another example, in the printed circuit board 100C according to another example, a magnetic structure 150C may further include a filler g disposed in a conductor layer 153. First and second pads 154 and 155 may further cover upper and lower surfaces of the filler g, respectively. The upper surface of the filler g may be substantially coplanar with each of an upper surface of a magnetic layer 151, an upper surface of an insulating film 152, and an upper surface of the conductor layer 153. The lower surface of the filler g may be substantially coplanar with each of a lower surface of the magnetic layer 151, a lower surface of the insulating film 152, and a lower surface of the conductor layer 153. Accordingly, the insulating layer 110 covering the same may also have more excellent flatness, thereby more easily forming a wiring layer 120 and a via layer 130.

The filler g may include an insulating ink including an insulating resin such as an epoxy or the like, but the present disclosure is not limited thereto, and may also include a conductive ink. For example, the filler g may include an insulating material and/or a conductive material. Other contents may be substantially the same as those described in connection with the printed circuit board 100A according to an example and the printed circuit board 100B according to another example, and thus repeated descriptions will be omitted.

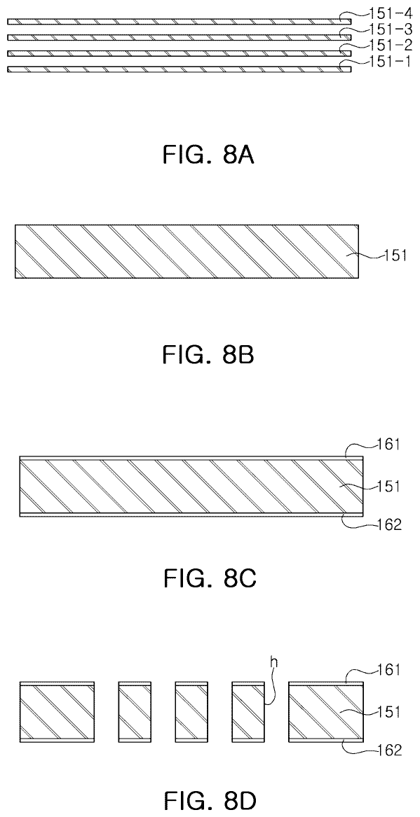

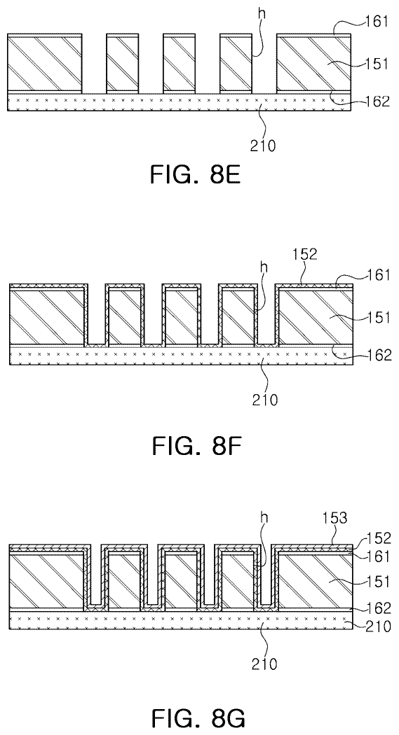

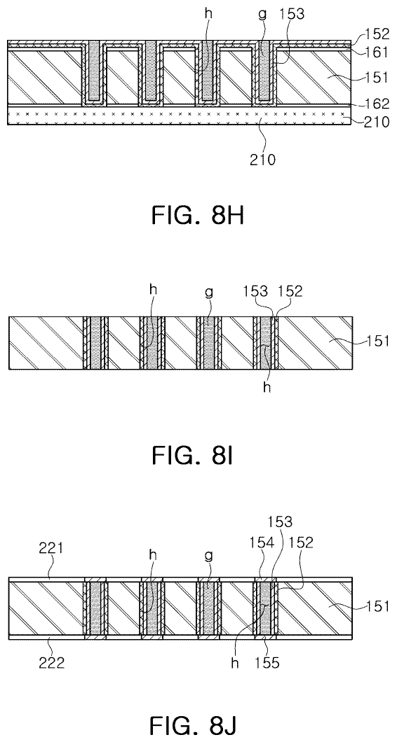

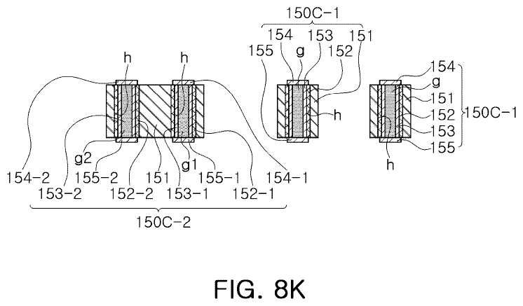

FIGS. 8A to 8K are schematic cross-sectional views of an example of manufacturing a magnetic structure of the printed circuit board in FIG. 7.

Referring to FIGS. 8A to 8F, a process, substantially the same as that described with reference to FIGS. 4A to 4F, may be performed.

Referring to FIG. 8G, a conductor layer 153 may be formed on an insulating film 152. The conductor layer 153 may conformally fill a portion of each of a plurality of through-holes h to a predetermined thickness. The conductor layer 153 may be formed using a plating process. For example, the conductor layer 153 may be formed using electroless plating, electrolytic plating, or the like.

Referring to FIG. 8H, a space between the conductor layers 153 may be filled with a filler g. The filler g may be formed using a plugging process.

Referring to FIG. 8I, a carrier film 210 may be removed to planarize upper and lower surfaces of a magnetic layer 151. During such a process, first and second cover layers 161 and 162, disposed on the upper and lower surfaces of the magnetic layer 151, the insulating film 152, the conductor layer 153, and the filler g may be removed. An upper side and/or a lower side of the magnetic layer 151 may be partially removed, as necessary, and at least a portion of each of the insulating film 152, the conductor layer 153, and the filler g may be further removed. Accordingly, flat upper and lower surfaces may be provided. As the planarization process, for example, a polishing process, such as CMP, may be used.

Referring to FIG. 8J, first and second resist layers 221 and 222, respectively having an opening pattern, may be formed on upper and lower surfaces of the magnetic layer 151, respectively, and the opening patterns may be filled with plating to form first and second pads 154 and 155. The first and second resist layers 221 and 222 may be formed by coating and curing solder resist or laminating a solder resist film. The first and second resist layers 221 and 222 may remain around the first and second pads 154 and 155, as necessary, even after a cutting process to be described below.

Referring to FIG. 8K, a cutting process may be performed. A plurality of magnetic structures 150C-1 and 150C-2 may be formed using the cutting process. At least one magnetic structure 150C-2, among the plurality of magnetic structures 150C-1 and 150C-2, may have a plurality of through-holes h, and insulating films 152-1 and 152-2, conductor layers 153-1 and 153-2, and fillers g1 and g2 may be respectively disposed in the plurality of through-holes h, and first pads 154-1 and 154-2 and second pads 155-1 and 155-2 may be respectively disposed on upper and lower sides of the plurality of through-holes h.

The plurality of magnetic structures 150C-1 and 150C-2, applicable to the printed circuit board 100C according to another example, may be formed using a series of processes. Other contents may be substantially the same as those described in connection with the printed circuit board 100A according to an example, the printed circuit board 100B according to another example, and the printed circuit board 100C according to another example, and thus repeated descriptions will be omitted.

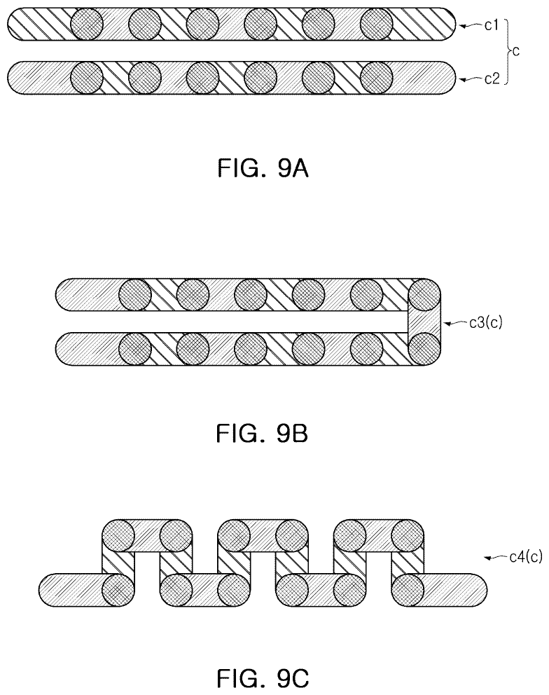

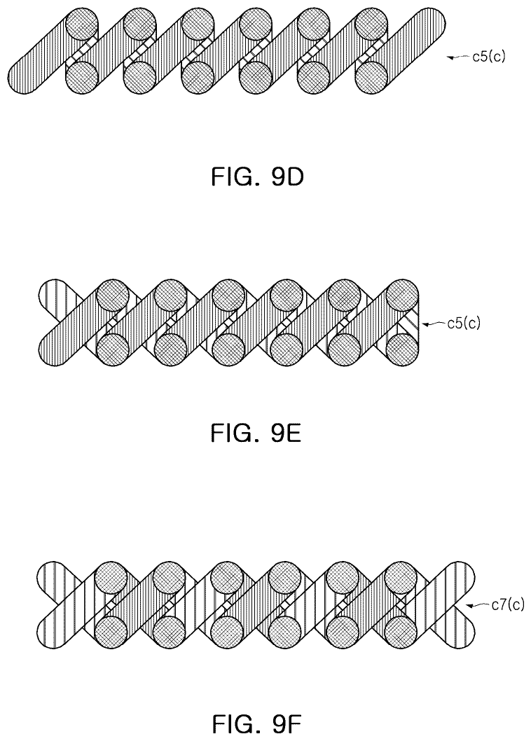

FIGS. 9A to 9F are schematic plan views of various examples of a coil applicable to the printed circuit boards in FIGS. 3, 5, and 7.

Referring to FIG. 9A, a coil portion c may include a plurality of coils c1 and c2, arranged in parallel in a straight line. The plurality of coils c1 and c2 may be disposed to be spaced apart from each other. Different wirings may be disposed between the plurality of coils c1 and c2.

Referring to FIG. 9B, the coil portion c may include a coil c3, arranged in a straight line and then bent at a right side to be arranged in a straight line again.

Referring to FIG. 9C, the coil portion c may include a coil c4, arranged to be repeatedly bent upward and downward.

Referring to FIG. 9D, the coil portion c may include a coil c5, repeatedly arranged to be inclined in one direction.

Referring to FIG. 9E, the coil portion c may include a coil c6, repeatedly arranged to be inclined in one direction, and then bent on a right side to be repeatedly arranged to be inclined again in an opposite direction.

Referring to FIG. 9F, the coil portion c may include a coil c7, repeatedly arranged to have an X-shape.

For example, the coil portion C including various shapes of coils c1, c2, c3, c4, c5, c6, and c7 may be applied to the above-described printed circuit boards 100A, 100B, and 100C. However, a shape of the coil portion C is not limited to the above-described examples. Other contents may be substantially the same as those described in connection with the printed circuit board 100A according to an example, the printed circuit board 100B according to another example, and the printed circuit board 100C according to another example, and thus repeated descriptions will be omitted.

As used herein, the terms “cover,” “to cover,” and “covering” may include entirely covering as well as at least partially covering, and may include directly covering as well as indirectly covering. In addition, the terms “fill,” to fill,” and “filling” may include not only entirely filling, but also approximately filling, for example, may include a case in which some voids, pores or the like are present. In addition, the terms “surround,” “to surround,” and “surrounding” may include not only entirely surrounding but also approximately surrounding. In addition, exposing may include not only entirely exposing but also exposing at least a portion of a structure, and exposure may mean exposing a component from another component in which the component is buried. For example, an opening exposing a pad may be exposing the pad from a resist layer, and a surface treatment layer or the like may be further disposed on the exposed pad.

As used herein, being disposed in a through-portion or a through-hole may include not only a case in which an object is completely disposed in the through portion or the through-hole, but also a case in which a portion of an object protrudes upwardly or downwardly in cross-section. For example, in plan view, a case in which an object is disposed in the through portion or the through-hole may be determined in a broader sense.

As used herein, a process error or a positional deviation occurring in a manufacturing process, an error in measurement, and the like may be included. For example, “substantially perpendicular” may include not only “completely perpendicular,” but also “approximately perpendicular.” In addition, “substantially coplanar” may include not only “completely coplanar,” but also “approximately coplanar.” For example, elements that are substantially coplanar may lie in planes that differ from each other by 1° or less and the distance between parallel planes may be 5% or less of the thickness of the conductor layer.

As used herein, the same insulating material may mean not only the exact same insulating material, but also the same type of insulating material. Thus, compositions of insulating materials may be substantially the same, but specific composition ratios thereof may slightly vary.

As used herein, “in cross-section” may refer to a cross-sectional shape of an object when the object is vertically cut, or a cross-sectional shape of the object when the object is viewed in a side-view. In addition, a shape on a plane may be a shape of the object when the object is horizontally cut, or a planar shape of the object when the object is viewed in a top-view or a bottom-view.

As used herein, an upper side, an upper portion, the upper surface, or the like is used to refer to a direction toward a surface on which an electronic component is mountable based on a cross-section of a drawing for ease, and a lower side, a lower portion, a lower surface, or the like is used to refer to an opposite direction thereof. However, the above-described directions are defined for ease of description. Thus, it should be understood that the scope of the claims is not particularly limited by the above-described directions, and the concepts of “upper” and “lower” may change at any time.

As used herein, the term “connected” may not only refer to “directly connected” but also include “indirectly connected” by means of an adhesive layer, or the like. The term “electrically connected” may include both of a case in which components are “physically connected” and a case in which components are “not physically connected.” In addition, the terms “first,” “second,” and the like may be used to distinguish a component from another component, and may not limit a sequence and/or an importance, or others, in relation to the components. In some cases, a first component may be referred to as a second component, and similarly, a second component may be referred to as a first component without departing from the scope of the example embodiments.

As used herein, thickness, width, length, depth, line width, space, pitch, separation distance, surface roughness, and the like may be measured using a scanning microscope or an optical microscope based on a cross-section obtained by polishing or cutting a printed circuit board. Other methods and/or tools appreciated by one of ordinary skill in the art, even if not described in the present disclosure, may also be used. The cross-section may be a vertical cross-section or a horizontal cross-section, and each value may be measured based on the required cross-section. For example, a width of an upper end and/or lower end of a via may be measured in cross-section taken along a central axis of the via. When the value is not constant, the value may be determined as an average value of values measured at five arbitrary points.

As used herein, the term “an example” does not mean the same example embodiment, and is provided to emphasize different unique features. However, the examples presented above do not preclude implementation in combination with features of other examples. For example, a context described in a specific example may be used in other examples, even if it is not described in the other example examples, unless it is described contrary to or inconsistent with the context in the other examples.

The terms used herein describe particular examples only, and the present disclosure is not limited thereby. As used herein, singular forms “a,” “an,” and “the” are intended to include the plural forms as well, unless the context clearly indicates otherwise.

While example embodiments have been shown and described above, it will be apparent to those skilled in the art that modifications and variations could be made without departing from the scope of the present disclosure as defined by the appended claims.

What is claimed is:

1. A printed circuit board comprising:
a magnetic structure including:
a magnetic layer having a through-hole,
an insulating film disposed on a wall surface of the through-hole, the insulating film including an inorganic insulating material, and
a conductor layer disposed on the insulating film, the conductor layer filling at least a portion of the through-hole, the conductor layer including a metal;
an insulating layer covering at least a portion of the magnetic structure;
a wiring layer disposed on or in the insulating layer; and
a via layer disposed in the insulating layer, the via layer including a first connection via connecting the conductor layer to the wiring layer.

2. The printed circuit board of claim 1, wherein the inorganic insulating material includes at least one of A1₂O₃, TiO₂, ZnO, ZnO₂, ZrO₂, SnO, SnO₂, HfO₂, and SiO₂.

3. The printed circuit board of claim 1, wherein, in a cross-section of the printed circuit board along a stacking direction and in a direction perpendicular to the wall surface of the through-hole, a width of the insulating film between the wall surface of the through-hole and a side surface of the conductor layer is less than a width of the magnetic layer between the wall surface of the through-hole and an external side surface of the magnetic layer.

4. The printed circuit board of claim 3, wherein, in the cross-section, the width of the insulating film between the wall surface of the through-hole and the side surface of the conductor layer is 2 μm or less.

5. The printed circuit board of claim 1, comprising a plurality of the magnetic structures, the plurality of the magnetic structures are disposed to be spaced apart from each other,
wherein the conductor layers in the plurality of the magnetic structures are connected to each other through the wiring layer and the via layer to form one or more coils.

6. The printed circuit board of claim 1, wherein
the magnetic layer has a plurality of the through-holes,
the insulating film and the conductor layer are disposed in each of the plurality of the through-holes, and
the conductor layers in the plurality of through-holes are connected to each other through the wiring layer and the via layer to form one or more coils.

7. The printed circuit board of claim 1, further comprising:
a first electronic component disposed in the insulating layer,
wherein the first electronic component includes at least one of a voltage regulator and a power management integrated circuit, and
the first electronic component is connected to at least a first portion of the conductor layer through the wiring layer and the via layer.

8. The printed circuit board of claim 7, further comprising:
a second electronic component disposed on the insulating layer,
wherein the second electronic component includes a semiconductor chip, and
the second electronic component is connected to at least a second portion of the conductor layer through the wiring layer and the via layer.

9. The printed circuit board of claim 1, wherein
the insulating layer includes:
a first insulating layer having a through portion in which at least a portion of the magnetic structure is disposed, and
a second insulating layer covering at least a portion of each of the first insulating layer and the magnetic structure, the second insulating layer filling at least a portion of the through portion,
the wiring layer includes:
a first wiring layer disposed on a first surface of the second insulating layer, and
a second wiring layer disposed on a second surface of the second insulating layer,
the first connection via includes a first-first connection via and a first-second connection via,
the first-first connection via passing through a first portion of a first side of the second insulating layer, the first-first connection via connecting a first surface of the conductor layer to at least a portion of the first wiring layer, and
a first-second connection via passing through a first portion of a second side of the second insulating layer, the first-second connection via connecting a second surface of the conductor layer to at least a portion of the second wiring layer.

10. The printed circuit board of claim 9, wherein
the wiring layer further includes:
a third wiring layer disposed on a first surface of the first insulating layer, the third wiring layer at least partially buried in the second insulating layer, and
a fourth wiring layer disposed on a second surface of the first insulating layer, the fourth wiring layer at least partially buried in the second insulating layer, and
the via layer further includes:
a third connection via passing through a second portion of the first side of the second insulating layer, the third connection via connecting at least a portion of the first wiring layer and at least a portion of the third wiring layer to each other,
a fourth connection via passing through a second portion of the second side of the second insulating layer, the fourth connection via connecting at least a portion of the second wiring layer and at least a portion of the fourth wiring layer to each other, and
a through via passing through the first insulating layer, the through via connecting at least a portion of the third wiring layer and at least a portion of the fourth wiring layer to each other.

11. The printed circuit board of claim 9, wherein the first-first and first-second connection vias are directly connected to the first and second surfaces of the conductor layer, respectively.

12. The printed circuit board of claim 9, wherein
the magnetic structure further includes:
a first pad disposed on the first surface of the conductor layer and a first surface of the insulating film, the first pad connected to the first surface of the conductor layer, and
a second pad disposed on the second surface of the conductor layer and a second surface of the insulating film, the second pad connected to the second surface of the conductor layer, and
the first-first and first-second connection vias are connected to the first and second pads, respectively.

13. The printed circuit board of claim 12, wherein
the magnetic structure further includes a filler disposed in the conductor layer,
the first and second pads further cover first and second surfaces of the filler, respectively.

14. The printed circuit board of claim 1, wherein the inorganic insulating material includes an inorganic oxide.

15. The printed circuit board of claim 14, wherein the inorganic oxide includes Zn, Sn, or both.

16. The printed circuit board of claim 14, wherein the inorganic oxide includes at least one selected from Al₂O₃, TiO₂, ZrO₂, HfO₂, and SiO₂.

17. The printed circuit board of claim 1, wherein the magnetic layer is in a form of a magnetic sheet.

18. A printed circuit board comprising:
a magnetic structure including:
a magnetic layer having a through-hole,
an insulating film disposed on a wall surface of the through-hole, and
a conductor layer disposed on the insulating film, the conductor layer filling at least a portion of the through-hole;
an insulating layer covering at least a portion of the magnetic structure;
a wiring layer disposed on or in the insulating layer; and
a via layer disposed in the insulating layer, the via layer including a connection via connecting the conductor layer to the wiring layer,
wherein a first surface of the magnetic layer, a first surface of the insulating film, and a first surface of the conductor layer are substantially coplanar with each other, and
a second surface of the magnetic layer, a second surface of the insulating film, and a second surface of the conductor layer are substantially coplanar with each other.

19. The printed circuit board of claim 18, wherein
the magnetic structure further includes:
a filler disposed in the conductor layer,
a first pad disposed on the first surface of the conductor layer, a first surface of the filler, and the first surface of the insulating film, and
a second pad disposed on the second surface of the conductor layer, a second surface of the filler, and the second surface of the insulating film,
the first surface of the filler is substantially coplanar with each of the first surface of the magnetic layer, the first surface of the insulating film, and the first surface of the conductor layer, and
the second surface of the filler is substantially coplanar with each of the second surface of the magnetic layer, the second surface of the insulating film, and the second surface of the conductor layer.

20. The printed circuit board of claim 18, further comprising:
a magnetic composite inductor (MCI) including the magnetic structure and at least a portion of the wiring layer connected to the magnetic structure.
